(19) United States
(12) Patent Application Publication
(10) Pub. No.: US 2003/0103459 A1
(43) Pub. Date: Jun. 5, 2003

(54) Method and implementation for a flow specific modified selective-repeat ARQ communication system

(76) Inventors: Dennis P. Connors, San Diego, CA (US); Hi Tai Huynh, San Diego, CA (US); Celio V. Albuquerque, Encinitas, CA (US); Nicos A. Antoniou, San Diego, CA (US)

Correspondence Address: FITCH EVEN TABIN AND FLANNERY, 120 SOUTH LA SALLE STREET, SUITE 1600, CHICAGO, IL, 60603-3406, US

(21) Appl. No.: 09/991,065

(22) Filed: Nov. 16, 2001

(51) Int. Cl. G01R 31/08; G06F 11/00; G08C 15/00; H04J 1/16; H04J 3/14

(52) U.S. Cl. 370/235; 370/230

(57) ABSTRACT

A method of automatic repeat request (ARQ) for a plurality of packets to be transmitted to a receiver, and a means for accomplishing the method, the method includes the step of: performing automatic repeat request for packets belonging to respective ones of a plurality of packet flows independent from and without affecting the transmission of packets of others of the plurality of packet flows, wherein each of the plurality of packet flows corresponds to a specified type of service. The packets belonging to the different flows are transmitted within the same transmit frame. In some variations, the method is implemented as a selective repeat ARQ method and may be used between any generic transmitter and receiver within a point to point system or a network topology, such as a wireless indoor local area network.

### BACKGROUND OF THE INVENTION

1. Field of the Invention

The present invention relates generally to controlling transmission errors which occur when packets are transmitted over a communication channel or link, and more specifically to methods of implementing automatic repeat request (ARQ) data transmission. Even more specifically, the present invention relates to methods of implementing selective-repeat ARQ data transmission in a peer-to-peer communication link.

2. Discussion of the Related Art

Automatic repeat request (ARQ) is a method for controlling transmission errors, which occur when packets are transmitted on a communications channel. As illustrated in FIG. 1, the basic components of an ARQ transmission system 100 are a sender 102, a receiver 104, a communications channel including a forward channel 106 and a feedback channel 108, a packet encoder 110, and an error detection 112.

There are multiple ways to implement an ARQ transmission system, such as, stop-and-wait ARQ go-back-N ARQ, and selective-repeat ARQ. Common to all techniques is the concept of an acknowledgement. An information-bearing packet (hereafter referred to as a packet) is received at the packet encoder 110 and encoded with an error detecting code. Once encoded, the sender 102 transmits the packet on the forward channel 106 and retains a copy of the packet in its memory. When the encoded packet crosses the channel, there exists the possibility that the packet may become corrupted with errors. When the packet is received at the receiver 104, the error detection 112 determines, using the error detecting code added to the packet, whether or not a channel error occurred. If an error occurred, ARQ information is forwarded from the receiver 104, which sends a negative acknowledgement (NACK) back to the sender 102 using the feedback channel 108. If the packet is received error free at the receiver 104, the receiver 104 sends a positive acknowledgement (ACK) back to the sender 102 using the feedback channel 108. The NACK indicates that the packet was received in error and the sender 102 will re-transmit that packet. The ACK indicates that the packet was received without error so that the sender can delete the packet from memory.

Referring next to FIG. 2, the basic method of selective-repeat ARQ is illustrated. Using selective-repeat ARQ, packets are continuously sent from the sender 102 to the receiver 104 without waiting for any acknowledgement, i.e., without waiting for the ACK or NACK from the receiver 104. Thus, packet number i+1 will be sent without needing the acknowledgment for packet number i. Once a packet is positively acknowledged by the receiver 104, i.e., the sender 102 receives an ACK from the receiver 104, the sender 102 will discard the packet from its memory. For example, once an ACK is received at the sender 102 for packet 2, packet 2 is discarded. If a packet is negatively acknowledged (NACK) by the receiver 104, the sender 102 will immediately, or at the next transmit opportunity, re-transmit this packet. For example, once the NACK is received for packet 3, packet 3 is re-transmitted, e.g., re-transmitted after packet 7 is transmitted. In this example, once the ACK is received for packet 3, it is then discarded from memory at the sender 102. Selective-repeat ARQ is the most efficient form of ARQ and is also the most complex. The complexity arises in the buffering of packet in memory required at both the sender 102 and receiver 104.

### SUMMARY OF THE INVENTION

The present invention advantageously addresses the needs above as well as other needs by providing fast, flow specific modified methods of selective repeat automatic repeat request (ARQ).

In one embodiment, the invention can be characterized as a method of automatic repeat request (ARQ) for a plurality of packets to be transmitted to a receiver, and a means for accomplishing the method, the method comprising the step of: performing automatic repeat request for packets belonging to respective ones of a plurality of packet flows independent from and without affecting the transmission of packets of others of the plurality of packet flows, wherein each of the plurality of packet flows corresponds to a specified type of service.

In another embodiment, the invention can be characterized as a method of automatic repeat request (ARQ) for a plurality of packets to be transmitted to a receiver comprising the steps of: performing automatic repeat request on a first set of one or more packets transmitted in a first portion of a transmit frame, wherein the first set of one or more packets belong to a respective one of a plurality of packet flows; and performing automatic repeat request on a second set of one or more packets transmitted in a second portion of the transmit frame, wherein the second set of one or more packets belong to another respective one of the plurality of packet flows, wherein the automatic repeat request performed on the first set of one or more packets is independent from and does not affect the transmission of packets in the second portion of the transmit frame.

In a further embodiment, the invention may be characterized as a method of automatic repeat request (ARQ) comprising the step of: assigning a time-to-live value to a packet to be transmitted over a forward communication channel to a receiver, the time-to-live value representing a maximum number of transmit attempts of the packet over the forward communication channel including re-transmit attempts using the automatic repeat request, the time-to-live value corresponding to a type of service corresponding to the packet.

### BRIEF DESCRIPTION OF THE DRAWINGS

The above and other aspects, features and advantages of the present invention will be more apparent from the following more particular description thereof, presented in conjunction with the following drawings wherein:

FIG. 1 is a simplified block diagram of the basic components of a conventional communication system using ARQ;

FIG. 2 is a diagram illustrating the basic methodology of conventional selective-repeat ARQ;

FIG. 3 is a diagram illustrating data packets organized into different flows to be transmitted from a sender or transmitter to a receiver according to one embodiment of the invention;

FIG. 4 is a functional block diagram of an ARQ system that performs flow specific modified methods of selective-repeat ARQ according to several embodiments of the invention;

FIG. 5 is a diagram illustrating that the selective repeat ARQ methods, performed by the system of FIG. 3 for example, for a given flow is independent of the selective repeat ARQ methods for other flows according to several embodiments of the invention;

FIG. 6 is a functional block diagram of one embodiment of the ARQ system of FIG. 4 illustrating a packet transmission mechanism of the sender and an acknowledgement generation and transmission of the receiver;

FIG. 7 is a flowchart illustrating the steps performed by the system of FIG. 6 to accomplish independent flow specific selective repeat ARQ according to several embodiments of the invention;

FIG. 8 is a flowchart illustrating the steps performed, for example, by a packet parser and a packet storage of the packet transmission mechanism of FIG. 6, when parsing an incoming stream of data packets into different flows and storing the packets to memory according to one embodiment of the invention;

FIG. 9 is an illustration of the searching function performed in parsing packets into memory and locating packets for transmission from memory according to one embodiment of the invention;

FIG. 10 is a flowchart illustrating the steps performed by the packet transmission mechanism of FIG. 4 or 6 when choosing which packets to transmit to the receiver according to one embodiment of the invention;

FIG. 11 is a flowchart illustrating the steps performed, for example, by a packet transmitter of FIG. 6 when generating a transmit packet array of packets to be transmitted to the receiver according to one embodiment of the invention;

FIG. 12 is a flowchart illustrating the steps performed, for example, by the acknowledgement processing mechanism of FIG. 4 or FIG. 6, when receiving acknowledgements from the receiver according to one embodiment of the invention; and

FIG. 13 is a flowchart illustrating the steps performed in assigning a time-to-live value to a given packet as a function of the type of service according to one embodiment of the invention.

Corresponding reference characters indicate corresponding components throughout the several views of the drawings.

### DETAILED DESCRIPTION

The following description is not to be taken in a limiting sense, but is made merely for the purpose of describing the general principles of the invention. The scope of the invention should be determined with reference to the claims.

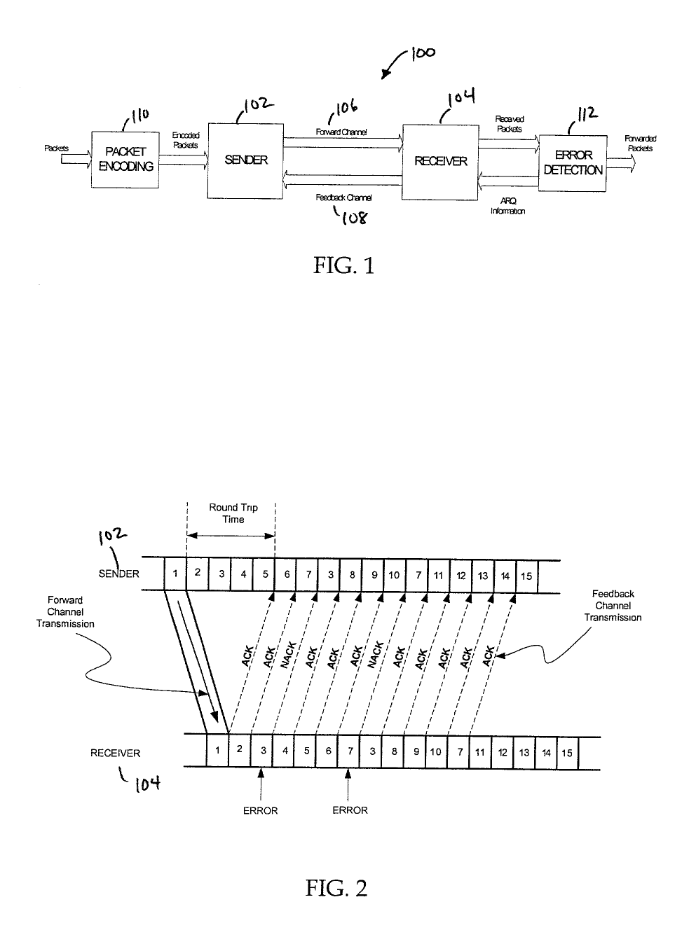

As described above, FIG. 1 is a simplified block diagram of the basic components of a conventional communication system using automatic repeat request (ARQ) and FIG. 2 is a diagram illustrating the basic methodology of conventional selective-repeat ARQ.

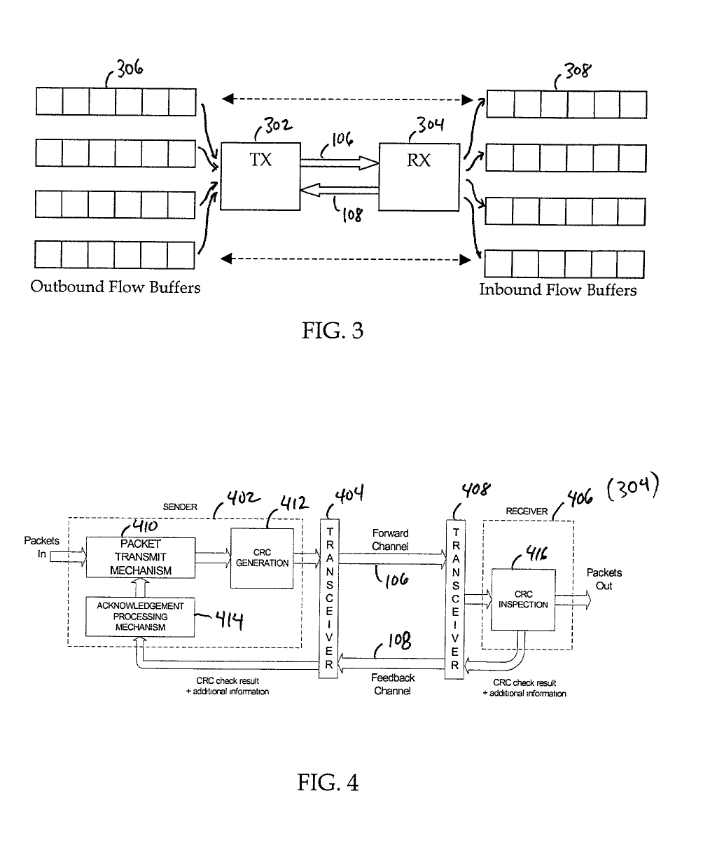

Referring next to FIG. 3, a diagram is shown illustrating data packets organized into different flows to be transmitted from a transmitter to a receiver according to one embodiment of the invention. Shown are a transmitter 302, a receiver 304, the forward channel 106 (also referred to as the forward communication channel), the reverse channel 108 (also referred to as the reverse communication channel), outbound flow buffers 306 and inbound flow buffers 308.

Several embodiments of the invention provide modified methods of selective repeat automatic repeat request (ARQ) in an environment where an incoming stream of data packets for transmission from the transmitter 302 to the receiver 304 are parsed or separated into different logical flows. Each flow is maintained in a respective outbound flow buffer 306 and is transmitted to the receiver 304 which places the inbound packets into respective ones of the inbound flow buffers 308. These flows represent a sequence of packets that has a sequential dependence on one another, originate from the same source or carry a common information stream. For example, one or more flows may contain voice packets, one or more flows may contain video packets and one or more flows may contain computer data packets. It is noted that there may be different flows of the same type of packet, for example, several different flows containing voice packets, e.g., representing several different voice calls. Each of these different types of packets (voice, video and data) in the respective logical flows have a separate type of service (TOS) requirement, e.g., the latency requirement and packet loss rate requirements are different for voice, video and data. For example, voice packets may have a latency requirement of 20 ms and can tolerate a packet loss rate of 104 while video packets may have a latency requirement of 4 ms and can tolerate a packet loss rate of 10⁻¹⁰. It is also noted that more than one flow may have the same type of service requirement.

Several embodiments of the invention provide ARQ for the packets transmitted from the transmitter 302 to the receiver 304 such that the ARQ for individual flows are not affected by the ARQ of other individual flows; thus, methods of flow independent or flow specific ARQ are provided herein. In some embodiments, the packets from different flows are transmitted in the same medium access control (MAC) frame. Thus, in effect, ARQ is performed on the packets of each flow separately. This means that the buffering, transmission, re-transmission, and forwarding of packets belonging to one flow are not affected by the buffering, transmission, re-transmission, and forwarding of packets belonging to another flow. It is noted that the flow specific or flow independent ARQ methods may be used with any known ARQ technique, such as stop-and-wait ARQ, go-back-N ARQ and selective-repeat ARQ.

Furthermore, in some embodiments, the total number of transmit attempts for a particular packet is limited according to the type of service (TOS) for the particular packet. These methods may be applied in the simple transmitter 302 and receiver 304 system or alternatively, may be employed in a network topology with many transceivers, each transmitting packets separated into one or more logical flows.

Referring next to FIG. 4, a functional block diagram is shown of an ARQ system that performs flow specific modified methods of selective-repeat ARQ according to several embodiments of the invention. Shown is a sender 402 coupled to transceiver 404 and a receiver 406 coupled to transceiver 408. The sender 402 includes a packet transmission mechanism 410, a cyclic redundancy check generation 412 (also referred to as the CRC generation 412), and an acknowledgement processing mechanism 414, while the receiver 406 includes a CRC inspection 416.

The packet transmission mechanism 410 receives packets and classifies them according to the flow to which they belong. These packets will then be placed into memory at the sender 402 in such a way that they can be retrieved for transmission and potential re-transmission, for example, stored in a respective one of the outbound flow buffers 306 of FIG. 3. The methodology for managing the storing of packets for transmission is independent of the actual scheduling of transmission and re-transmission on the channel. When the time comes for transmission, the packet transmission mechanism 410 provides a means for sequential retrieval of packets belonging to a particular flow that are being transmitted for the first time. The packet transmission mechanism 410 also provides a means for retrieval of packets belonging to a particular flow that are being re-transmitted. The order of these re-transmitted packets will be the order in which they arrived at the packet transmission mechanism 410.

At transmission, the CRC generation 412 adds the error detection feature (e.g., a CRC sequence) to the packets for transmission. The packets are transmitted by the transceiver 404 over the forward channel 106 to the receiver 406. The packets are received by the transceiver 408 and forwarded to the CRC inspection 416 of the receiver 406. At the CRC inspection 416, a CRC check is performed. The result of the CRC check will generate an ACK, if the packet was received without error, or a NACK, if the packet was received with an error. This ACK/NACK information will be transmitted back to the sender 402 via the feedback channel 108. Positively acknowledged packets are forwarded out to be placed into the respective logical flows, for example, placed into a respective one of the inbound flow buffers 308 of FIG. 3.

The acknowledgement processing mechanism 414 receives the acknowledgement information transmitted by the receiver 406 on the feedback channel 108 and with this information, discards and/or re-orders previously transmitted packets so as to accomplish selective-repeat ARQ. It also performs packet re-ordering with the number of previous transmit attempts values as input, discarding packets that would otherwise have been re-transmitted if it were not for the fact that they have expired their maximum number of transmit opportunities. In other words, packets that have exceeded the maximum number of transmit attempts, or time-to-live value, are discarded.

The novelty of several embodiments of the invention resides in the method for performing flow specific modified selective-repeat ARQ, which is implemented in the packet transmission mechanism 410 and the acknowledgement processing mechanism 414 of the sender 402. It is noted that the sender 402 and the transceiver 404 collectively constitute the transmitter 302 of FIG. 3 and the transceiver 408 and receiver 406 collectively constitute the receiver 304 of FIG. 3. The transmitter 302 and receiver 304 pair can be any generic transmitting and receiving system. The CRC generation 412 and CRC inspection 416 can be realized by any CRC polynomial.

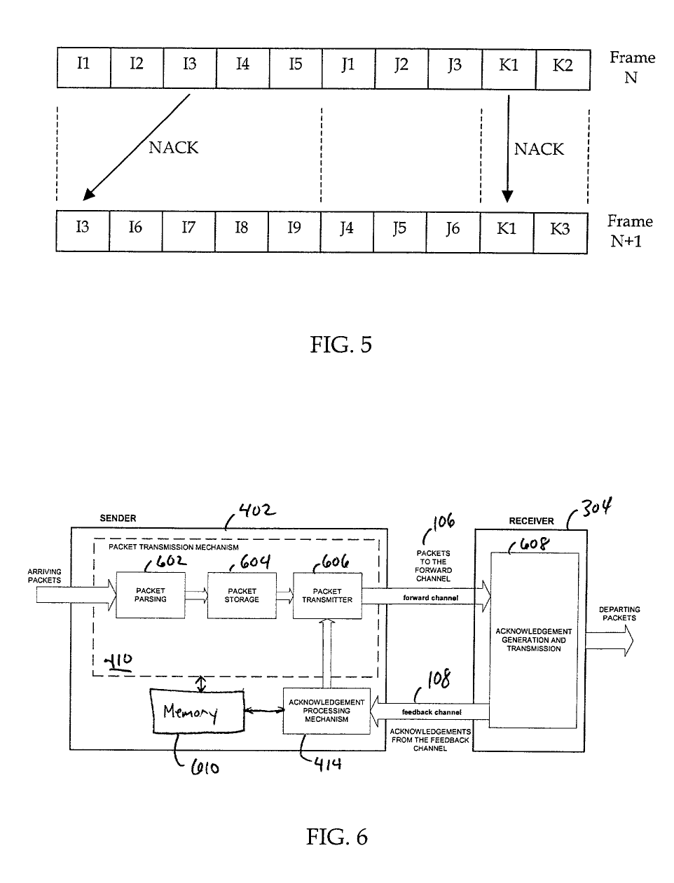

Referring next to FIG. 5, a diagram is shown illustrating that the selective repeat ARQ of several embodiments of the invention, for example, performed by the system of FIG. 3, for a given flow is independent of the selective repeat ARQ for other flows according to several embodiments of the invention.

In one embodiment, packets belonging to different flows are transmitted in the same medium access control (MAC) frame to the receiver. These packets are transmitted according to a transmit descriptor that specifies how many packets of which packet flows are to be transmitted to the receiver. For example, as shown in Frame N (also referred to as transmit frame N) of FIG. 5, a transmit descriptor specifies that 5 packets of flow I will be transmitted, 3 packets of flow J will be transmitted and 2 packets of flow K will be transmitted. Thus, the MAC frame N includes packets I1-I5, J1-J3 and K1 and K2. It is noted that the transmit descriptor effectively partitions the transmit frame into different portions, each portion containing packets that belong to a specific flow. The example illustrated is a simple transmit frame; however, it should be recognized that the specific length of the frame and assignment of packet from different flows is entirely system dependent.

By way of example, assuming that a negative acknowledgement (NACK) is received for packets I3 and K1, then according to selective repeat ARQ, the sender will re-transmit packets I3 and K1 at the next available transmit opportunity. Thus, in Frame N+1 (also referred to as transmit frame N+1) using the same transmit descriptor, Frame N+1 includes packets I3, I6-I9, J4-J6 and K1 and K3. As is clearly seen, the re-transmission of packet I3 does not affect the transmission of packets in the J or K flows. For example, assuming packets J1-J3 are positively acknowledged, packets J4-J6 are transmitted in Frame N+1 regardless of the result of the acknowledgement of the packets in flows I and K. Therefore, the ARQ of flow J is independent of the ARQ of flows I and K, and the ARQ of flow I is independent of the ARQ of the flows J and K. Thus, as can be seen in this simple example, according to several embodiments of the invention, the ARQ for each flow of packets is independent of the ARQ of other packet flows. Thus, flow specific or flow independent ARQ methods are provided herein. These flow independent techniques apply to all known ARQ methods, such as stop-and-wait ARQ, go-back-N ARQ and selective-repeat ARQ.

Referring next to FIG. 6, a functional block diagram is shown of one embodiment of the ARQ system of FIG. 4 illustrating a packet transmission mechanism of the sender and an acknowledgement generation and transmission of the receiver. Shown are the sender 402, the receiver 304, the forward channel 106 and the reverse channel 108. The sender 402 includes the acknowledgement processing mechanism 414, a memory 610 and the packet transmission mechanism 410 including a packet parser 602, a packet storage 604 and a packet transmitter 606. The receiver 304 includes an acknowledgement generation and transmission module 608.

At the sender 402, the functional components of the packet transmission mechanism 410 and the acknowledgement processing mechanism 414 may be embodied in hardware or as a set of instructions executed by a processor or other machine, for example. Both the packet transmission mechanism 410 and the acknowledgement processing mechanism 414 are coupled to the memory 610.

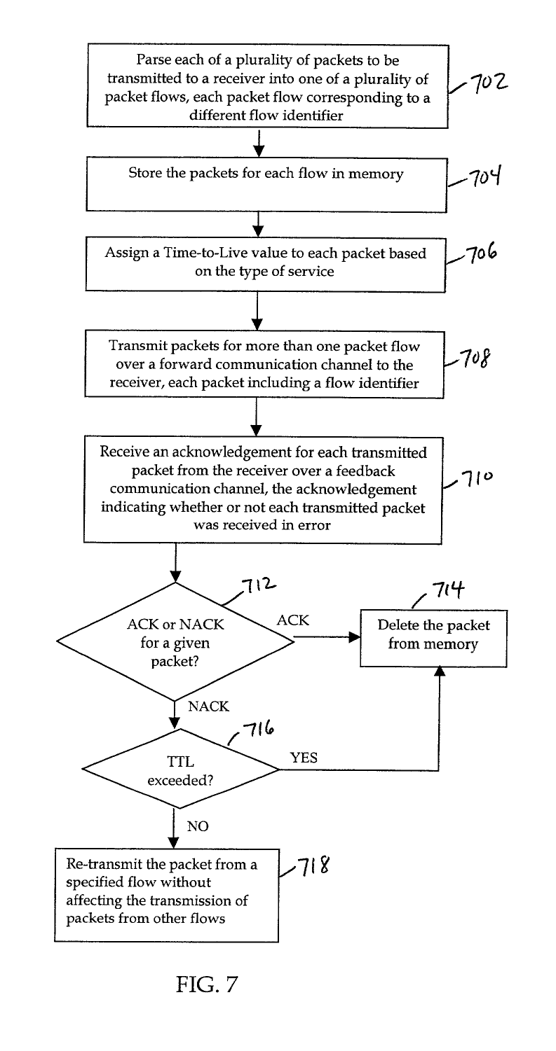

While referring to FIG. 6, concurrent reference will be made to FIG. 7, which is a flowchart illustrating the steps performed by the system of FIG. 6 to accomplish independent flow specific selective repeat ARQ according to several embodiments of the invention.

According to the ARQ methods of several embodiments of the invention, incoming packets are received at packet transmission mechanism 602 of the sender 402. These incoming packets are received from any higher layer in the communication system stack and each of the incoming packets belongs to a particular flow. The incoming or arriving packets are to be sent to one or more receivers, e.g., receiver 304.

In the packet transmission mechanism 402, each of the packets are parsed into one of a plurality of packet flows, each packet flow corresponding to a flow identifier (Step 702 of FIG. 7). Note that each packet flow also has a type of service associated therewith. This parsing is performed at the packet parser 602. In one embodiment, the packet parser 602 reads the header or control information for each packet in order to parse the packet. In other embodiments, the flow information may be received at the packet parser 602 from the higher layers via a signaling protocol, rather than be included within the packets themselves.

In one embodiment, this flow information comprises a flow identifier. Thus, for each flow, a flow identifier (FID) is needed. The FID is made up of two entries: a type of service (TOS) indicator, and a flow number (FN). The FID field is used by the packet parser 602 to uniquely identify the packets of each flow. The TOS indicator identifies the type of application producing the packets that make up this flow, e.g., voice, video, data, etc., and the FN identifies a particular flow within a TOS category. For example, the flow number (FN) is used to distinguish flows having the same TOS indicator. The FID can be carried within each packet or it can be communicated to the packet transmission mechanism 410 via a signaling protocol. The packet parser 602 needs the FID to properly organize packets in the event there are simultaneous flows arriving to it.

Furthermore, within a particular flow, the packet parser 602 assigns a sequence number (SEQNO) for all of the arriving packets. The sequence number is used to identify a particular packet for the purposes of sequencing within the packet transmission mechanism 410, acknowledging (either positively or negatively) by the receiver 304, and re-transmitting by the sender 402.

Next, the parsed packets for each flow are stored in memory 610 (Step 704 of FIG. 7) at the sender 402. The flow identifier is used to store the packet in memory 610. In one embodiment, the packet storage 604 performs Step 704 and is coupled to the memory 610 at the sender 402.

In order to store the packets in memory (Step 704 of FIG. 7), the packet storage 604 engages in a search algorithm to determine the location within the memory 610 in which the packet should be placed. In some embodiments, this searching will be aided by the combination of a cache table and a hash table. If the flow is found, the packet storage 604 stores the arriving packet in next location in the same array of memory 610. If the flow is not found, the packet storage 610 allocates a new array of memory 610 then stores the arriving packet in that new array. In alternative embodiments, if a flow is not found, the packet is discarded.

The memory 610 may be arbitrarily sized and easily manageable memory buffers to store the incoming packets into logical flows, e.g., the memory 610 includes the outbound flow buffers 306 of FIG. 6. In preferred embodiments, the memory 610 comprises a linked list of array memory (LLOAM).

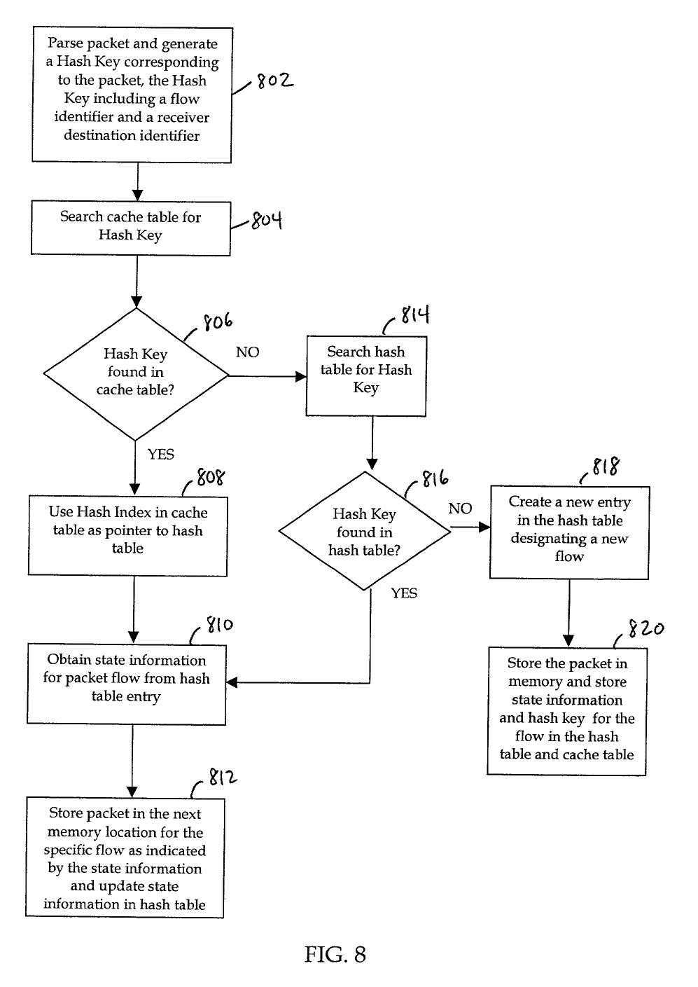

It is noted that in some embodiments, the incoming packets may already be parsed into separate flows, such that the functionality of the packet parser 602 is not required. Thus, the packet storage 604 simply stores the arriving packets in the appropriate location in memory depending upon the flow. It is also noted that the sequence of the packets in these flows may already be assigned or alternatively, the packet storage assigns the packet sequence number. Thus, the functionality of the packet parser 602 and the packet storage 604 functional blocks of FIG. 6 may be illustrated as one functional block in FIG. 6. Further details of the parsing (Step 702) and storing (Step 704) steps of FIG. 7 are described with reference to FIG. 8.

The FN sub-field of the FID is used to identify a particular flow within a TOS category. The TOS sub-field of the FID gives the ARQ algorithm a means for tailoring the exact method for performing selective-repeat ARQ on a flow type specific basis. There are several ways in which the ARQ algorithm can be made flow type specific. For example, each individual flow is identified and separated using the combination of FN and TOS. This allows state information pertaining to individual flows to be maintained in the packet transmission mechanism 410. In another example, packets of a given TOS category are allowed a maximum number of transmit opportunities. This value is referred to a time-to-live (TTL). This allows for the total bandwidth used by an individual flow and the delay across the communication system to be bounded. This TTL parameter is specific to a TOS category. Therefore, the packet parser 602 (or alternatively, the packet storage 604) assigns a time-to-live value to each packet based on the type of service (TOS) of the packet (Step 706 of FIG. 7). The TTL value equates to the maximum number of transmission attempts for the packet, including the initial transmission attempt plus re-transmission attempts using ARQ.

To illustrate the concept of a time-to-live value, take the case where packets of a particular flow have a TOS sub-field of type j. Assuming TOS category j has a TTL value of 2, after the initial transmission of the packet, there will be only one more transmit attempt if this packet is negatively acknowledged. If after the second transmission attempt, the packet is still negatively acknowledged, the packet has exceeded its time-to-live value and will be discarded by the packet transmission mechanism 410. Effectively for all packets of TOS category j, there will be one initial transmission and at most TTL-1 (in this case only one) re-transmissions in the event that a packet is negatively acknowledged. This technique provides a flow type specific upper bound on the number of times a packet can be transmitted. This mechanism is essential in bounding the time between when a packet enters the packet transmission mechanism 410 of the sender and when it leaves the receiver. In a further example, in some systems, the packet delay for a video packet must be less than 4 msec. If the MAC frame that transmits the packet is 1 msec in length, there is only time for 1 initial transmission attempt and 3 re-transmission attempts. After 4 msec, the packet is no longer useful to the receiver. Therefore, if it is not received error-free at the receiver within 4 msec, then it may be discarded at the transmitter.

Such a time-to-live value is different than known systems that discard a packet after a determination that the channel conditions are not good and not amount of re-transmitting will result in a positive acknowledgement. The time-to-live automatically sets a limit on the total number of transmission attempts based on the type of service (TOS), not the conditions of the channel.

In such embodiments employing the time-to-live, a lookup table is maintained in the memory 610. The lookup table matches a given TOS to a corresponding TTL. The TTL value assigned to each packet may be stored with the packet in the memory 610 or may be maintained in a separate location in the memory 610.

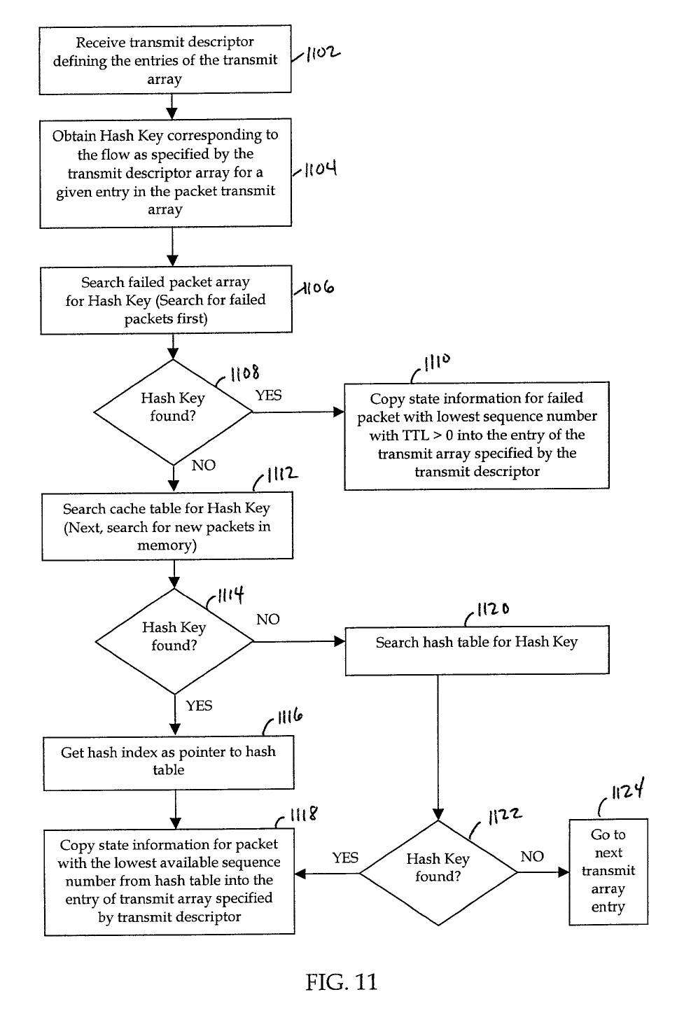

Next, after the packets have been parsed and stored and have been assigned a time-to-live value, the packets from one or more packet flows are transmitted over the forward channel to the receiver, each packet including its flow identifier (Step 708 of FIG. 7). In one embodiment, this step is performed by the packet transmitter 606, e.g., via the transceiver 404 of FIG. 4. According to one embodiment, the packet transmitter 606 forms a transmit array of packets as specified by a transmit descriptor. The transmit descriptor indicates at least how many packets of which flows are to be included in the transmit array. When generating the transmit array, the packet transmitter 606 first looks to see if there are packets from a particular flow as specified by the transmit descriptor that need to be re-transmitted before looking for new packets (i.e., packets not already having been initially transmitted) from the particular flow as specified by the transmit descriptor. The transmit array specifies which packets, and in which order, are to be placed on the transmit MAC frame and transmitted. In one embodiment, a CRC sequence is appended to each transmit array (e.g., by the CRC generation 412 of FIG. 4) to assist the receiver in determining if the packets were received in error. Further details regarding the step of transmitting the packets over the forward channel are described with reference to FIG. 11.

Once the packets have been transmitted, the receiver 304 receives the packets and determines whether or not each packet of the transmit array was received in error. In one embodiment, the receiver 304 performs a CRC check on each packet at the acknowledgement generation and transmission 608. The result of this CRC check will be either a PASS or FAIL (corresponding to an ACK or a NACK). The receiver generates acknowledgements and transmits these acknowledgements on the feedback channel in the form of an ARQ bit map. The use of the term bit map is possible because the CRC check result is a binary value (PASS or FAIL). Once a particular ARQ bit map is formed, it is encapsulated to form an ARQ response. The response includes information for the sender 402 to match a particular ARQ bit map with the particular transmit array of packets that it is acknowledging. The order of the ARQ bit map will follow the order in which the packets were transmitted by the sender 402 (and therefore the same order that they were received at the receiver 304). A CRC sequence is generated and appended to the ARQ response so that ARQ can be performed on the acknowledgement and response from the receiver 304 in the event that the feedback channel 108 is itself unreliable. The ARQ response in then transmitted back to the sender 402 via the feedback channel 108.

Next, at the acknowledgement processing mechanism 414 of the sender 402, an acknowledgment for each transmitted packet is received via the feedback channel, the acknowledgement indicating whether or not each of the transmitted packets were received in error (Step 710 of FIG. 7). Thus, an ACK or a NACK is received for each transmitted packet. In one embodiment, the acknowledgement is received as an ARQ bit map. Thus, the acknowledgement processing mechanism 414 compares the received ARQ bit map with all entries in the transmit array to identify the packets that were received in error.

Generally, if an ACK is received for a given packet of a given flow (Step 712 of FIG. 7), then the packet was successfully transmitted error-free and the packet is deleted from memory 610 at the sender 402 (Step 714 of FIG. 7).

If a NACK is received for a given packet of a given flow (Step 712 of FIG. 7), then the packet was received in error. If the time-to-live (TTL) for the particular packet would be exceeded if the packet was to be re-transmitted (Step 716 of FIG. 7), then the packet is deleted from memory at the sender 402 (Step 714 of FIG. 7). For example, based on the type of service for the packet, if the TTL is a value of 3 and the total number of transmission attempts if re-transmitted would exceed 3, then the packet is deleted since the packet delay would be exceeded for the particular packet (i.e., the packet is not longer useful at the receiver). In other words, if the total number of transmissions of the packet is equal to the TTL assigned to the packet, then the packet is discarded rather than re-transmitted again.

If the time-to-live (TTL) for the particular packet of the given flow would not be exceeded if the packet was to be re-transmitted (Step 716 of FIG. 7), then the packet from the given flow is re-transmitted without affecting the transmission of packets from other flows (Step 718 of FIG. 7), e.g., as illustrated in FIG. 5. The re-transmission typically occurs at the next transmit opportunity, e.g., when the next transmit array is generated. Further details regarding Steps 710, 712, 714 and 718 are described with reference to FIG. 12.

It is noted that the steps of FIG. 7 may be performed by the functional structure of the packet transmission mechanism 410 and the acknowledgement processing mechanism 414 of FIG. 6. The steps of FIG. 7 are typically performed as a set of instructions that are performed in dedicated hardware or in software using a processor or other machine to execute the instructions to accomplish the given steps.

Referring next to FIG. 8, a flowchart is shown illustrating the steps performed, for example, by the packet parser and the packet storage blocks of the packet transmission mechanism of FIG. 6, when parsing and storing an incoming stream of data packets into different flows according to one embodiment of the invention.

It is noted that when referring to FIGS. 8 and 10-12, the following definitions listed in Table 1 are of assistance.

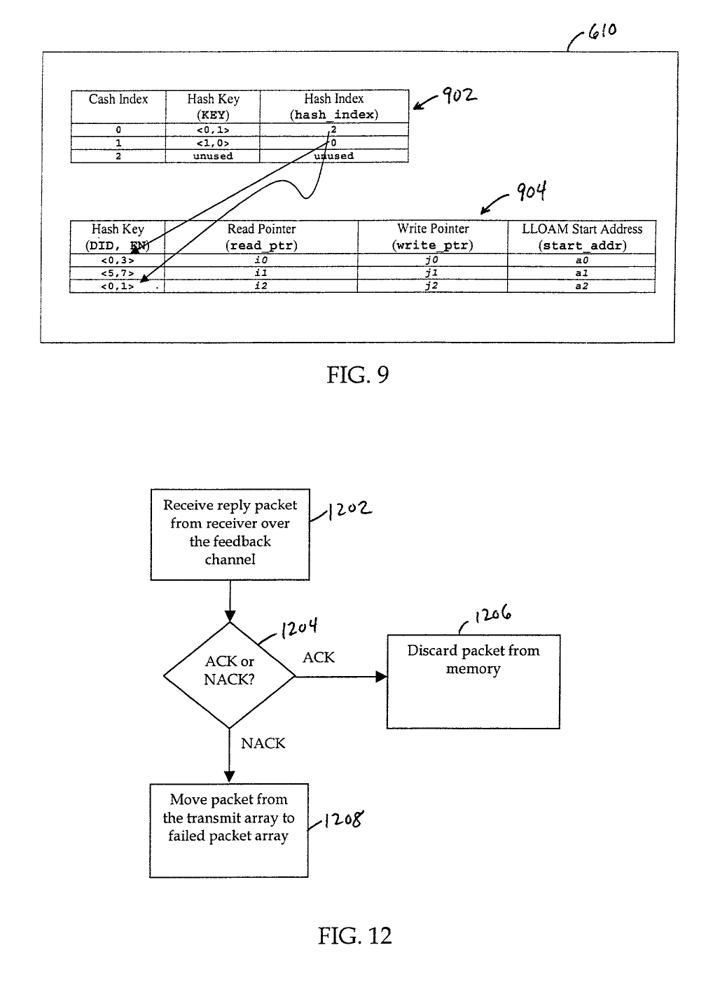

It is noted that while referring to FIG. 8, concurrent reference will be made to FIG. 9, which is an illustration of the searching function performed in storing of packets into memory and locating packets for transmission from memory according to one embodiment of the invention. FIG. 9 illustrates one embodiment of the memory 610 of FIG. 6, e.g., the memory comprises a linked list of array memory (LLOAM). FIG. 9 includes a cache table 902 and a hash table 904.

TABLE 1

| | |
|---|---|
| New Packet | Packet contained within a New Packet Array |
| Failed Packet | Packet contained within a Failed Packet Array |
| Reply Packet | A packet transmitted by the receiver to the |
| | sender via the feedback channel that indicates |
| | the result of a previous transmission of a |
| | packet on the forward channel |
| New Packet | An array of memory at the sender, set aside |
| Array | on a per FID basis, used to store newly |
| | arriving packets |
| Failed Packet | An array of memory at the sender, set aside |
| Array | on a per FID basis, used to store packets that |
| | have been transmitted and subsequently |
| | negatively acknowledged |
| Transmit Array | An array of memory at the sender where |
| | packets that are sent on the channel are stored |
| | until an acknowledgement (either positive or |
| | negative) is received |
| Received Packet | An array of memory at the receiver, set aside |
| Array | on a per FID basis, used to store packets that |
| | have been received via the forward channel |
| Transmit Instant | An instant in time at which the sender |
| | receives authorization to transmit a packet |
| | belonging to a designated FID |

As noted earlier, each arriving packet belongs to a particular flow. The packet parser parses the incoming packets and the packet storage stores them in memory. According to one embodiment, the packet storage engages in a search algorithm to determine the memory location in which the packet should be placed. In preferred embodiments, this searching will be aided by the combination of a cache table and a hash table. If the flow is found, the packet storage stores the arriving packet in next location in the same array of memory. If the flow is not found, the packet storage allocates a new array of memory for a new flow and stores the arriving packet in that new array. In alternative embodiments, if the flow is not found, the packet is simply discarded.

In some embodiments, it is desirable that the system is capable of handling an ever-increasing number of distinct flows. To accommodate this, a combination of a cache table 902 and a hash table 904 is utilized to speed up the searching process. When a packet arrives, the packet is parsed to generate a hash key (Step 802). This hash key is a concatenation of the flow identifier (FID) and the receiver destination identifier (DID). Thus, the FID indicates which flow the packet belongs to and which receiver the packet is destined for, in the event there are more than one receiver that the sender communicates with. For example, the hash key is in the format: KEY=<DID, FID>. The hash key may be a part of the header or control information portion of the packet or may be communicated to the packet parser from the higher layers in a signaling protocol.

Once the hash key is obtained for a particular packet, the cache table 902 is searched to see if the hash key is present (Step 804). If the hash key is found in the cache table 1102 (Step 806), a hash index found in the cache table entry for the hash key is used as a pointer to the hash table 904 (Step 808). Thus, as shown in FIG. 9, the cache table entry for a particular hash key also contains a hash index (hash_index) value. Using this hash index as a pointer to the hash table 904, an entry at this index in the hash table 904 is examined and state information is obtained for the packet flow denoted by the hash key (Step 810). For example, and as illustrated in FIG. 9, the hash_index for hash key entry <0,1> in the cache table 902 points to an entry in the hash table 904 that contains the state information for a particular packet flow. In one embodiment, the state information includes a read pointer, a write pointer and an LLOAM start address (also referred to as a memory start address).

Next, the packet is stored in the next memory location for the specific flow as indicated by the state information and then the state information in the hash table 904 is updated (Step 812).

If the hash key is not found in the cache table 902 (Step 806), the hash table 904 itself is searched for the hash key (Step 814). In the event that no key is found in the hash table 1104 (Step 816), a new entry is created in the hash table 904 and a new flow is established (Step 818). This entry in the hash table 904 will contain a pointer to the starting memory location of the linked list of array memory (LLOAM), which will hold packets for this new flow. The entry will also contain state information pertaining to the flow such as read/write pointers, pointers to the last positively acknowledged packet, packet count, and any other necessary state variables to manage the flow. Then, the packet is stored in memory and the state information and hash key for the new flow is stored in the hash table 904 and the hash key and the hash_index are stored in the cache table 902 (Step 820). It is noted that in alternative embodiments, if no key is found, the packet is simply discarded.

In the event that the hash key is found in the hash table 904 (Step 816), Steps 810 and 812 are performed.

With reference to FIG. 9, it is noted that this is only one example of a search algorithm using a cache and hash tables. In other embodiments, there may be a separate hash table for each type of service, i.e., there is one cache table and multiple hash tables. For example, the cache table would include a hash key, a hash table select and the hash index. The hash table select points to a specific hash table for the type of service for the flow.

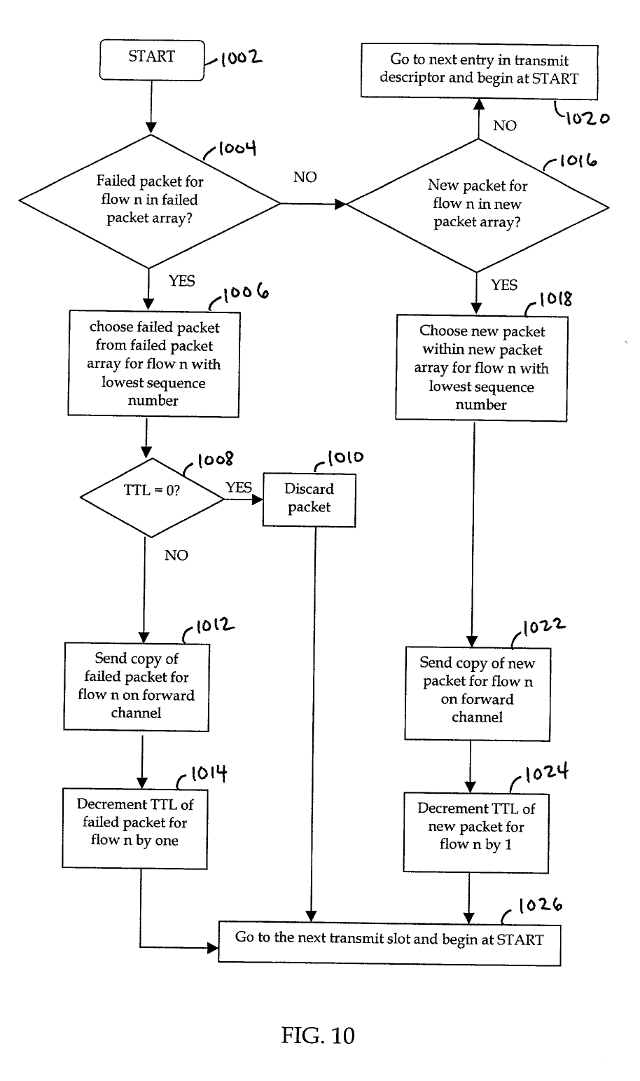

Referring next to FIG. 10, a flowchart is shown illustrating the steps performed by the packet transmission mechanism of FIG. 4 or 6 when choosing which packets to transmit to the receiver according to one embodiment of the invention. In one embodiment, the steps performed FIG. 10 are performed by the packet transmitter 606 of FIG. 6.

The process begins, e.g., with packet transmitter 606, at the Start block 1002. It is noted that the packet transmitter 606 is coupled to the memory 610 of FIG. 6. First, the packet transmitter looks in the failed packet array for failed packets of a specified flow n. If there is a failed packet for flow n in the failed packet array (Step 1004), then the packet transmitter chooses the failed packet from the failed packet array for flow n that has the lowest sequence number (Step 1006). Once chosen, the time-to-live value (TTL) associated with the failed packet is checked. If the TTL equals zero (Step 1008), then the failed packet is discarded (Step 1010) and the process goes to the next packet slot and begins again with the Start block 1002 (Step 1026). In other words, if the total number of transmission attempts (i.e., the TTL value) would be exceeded if the failed packet were to be re-transmitted, the failed packet is no longer useful at the receiver and the packet is deleted.

If the TTL value is not equal to zero (Step 1008), then a copy of the failed packet for flow n is re-transmitted on the forward channel (Step 1012) and the TTL value is decremented by one (Step 1014). In one embodiment, the failed packet is transmitted by placing the state information for the failed packet at the desired location of the transmit array so that it will be transmitted. Then, the algorithm goes to the next packet slot and begins again with the Start block 1002 (Step 1026).

If there are no failed packets for flow n in the failed packet array (Step 1004), then the new packet array for flow n is checked. If there is a new packet for flow n in the new packet array (Step 1016), then the packet transmitter chooses the new packet from the new packet array for flow n that has the lowest sequence number (Step 1018).

Next, a copy of the new packet for flow n is transmitted on the forward channel (Step 1022) and the TTL value is decremented by one (Step 1024). Then, the process goes to the next packet slot and begins with again with the Start block 1002 (Step 1026).

If there are no new packets for flow n in the new packet array (Step 1016), then the packet transmitter moves to the next entry in the transmit descriptor and begins with the Start block 1002 (Step 1020).

Referring next to FIG. 11, a flowchart is shown illustrating the steps performed, for example, by a packet transmitter of FIG. 6 when generating a transmit packet array of packets to be transmitted to the receiver according to one embodiment of the invention. The steps in FIG. 11 illustrate one embodiment of the steps performed by the packet transmitter 606 of FIG. 6 when performing Step 708 of FIG. 7.

When a transmit opportunity comes, the packet transmitter forms a transmit array. A transmit array is an array of memory at the sender where packets that are sent on the channel are stored until an acknowledgement (either positive or negative) is received. The transmit array specifies which packets and in which order the packets will be placed on the transmit frame. In some embodiments, the transmit descriptor also specifies the destination of the packets. The size of the transmit array is equal to the number of packets authorized to be transmitted at this transmit opportunity. In one embodiment, the format of the transmit array is illustrated in Table 2.

TABLE 2

| Entry 1 | Entry 2 | Entry 3 | . . . | Entry N |
|---|---|---|---|---|
| KEY | KEY | KEY | . . . | KEY |
| hash_index | hash_index | hash_index | . . . | hash_index |
| ptr - pointer | ptr - pointer | ptr - pointer | . . . | ptr - pointer |
| to memory | to memory | to memory | | to memory |
| address | address | address | | address |
| where | where | where | | where |
| packet | packet | packet | | packet |
| resides | resides | resides | | resides |

To form this transmit array, the packet transmitter receives a transmit descriptor that defines the entries of the transmit array (Step 1102). Thus, the transmit descriptor indicates what flows will be transmitted and how many packets from each flow to transmit. The transmit descriptor will also indicate the order of transmission. The first entry in the transmit descriptor is used to fill the transmit array before the packet transmitter considers the next entry in the transmit descriptor. One embodiment of a transmit descriptor is shown in Table 3.

TABLE 3
Transmit Descriptor

did = a, flow = i, quantity = Qᵢ
did = a, flow = j, quantity = Qⱼ
did = b, flow = k, quantity = Qₖ
did = c, flow = l, quantity = Qₗ

As can be seen in Table 3, the transmit descriptor specifies what destination of packets (in the event there are more than one receiver that the sender communicates with), the flow of the packets and the quantity of packets to be transmitted for each flow. One example of a simple transmit descriptor is described with reference to FIG. 5 and illustrated in Frame N and Frame N+1 where the transmit descriptor specifies that 5 packets of flow I will be transmitted, 3 packets of flow J will be transmitted and 2 packets of flow K will be transmitted. In the example of FIG. 5, the destination (DID) is the same for each flow.

When the transmit descriptor is received by the packet transmitter, it locates the packets to transmit for each flow in memory. A similar searching algorithm shown in FIG. 9 is used to find the packets in memory to transmit for each flow. Since a flow is equivalent to a hash key (i.e., DID and FID), the hash key is obtained that corresponds to the flow specified by the transmit descriptor for a given entry in the transmit array (Step 1104). Then the failed packet array is searched for the hash key (Step 1106). In other words, when looking for packets to transmit, the packet transmitter first looks for failed packets, i.e., packets that have been negatively acknowledged.

The failed packet array is an array of memory at the sender, set aside on a per FID basis, used to store packets that have been transmitted and subsequently negatively acknowledged. Thus, when a transmitted packet is negatively acknowledged, if it has not expired its time-to-live value (TTL), it is placed in the failed packet array. In one embodiment, the failed packet array has the form shown in Table 4.

TABLE 4

| Entry 1 | Entry 2 | Entry 3 | . . . | Entry N |
|---|---|---|---|---|
| KEY | KEY | KEY | . . . | KEY |
| hash_index | hash_index | hash_index | . . . | hash_index |
| ptr - pointer | ptr - pointer | ptr - pointer | . . . | ptr - pointer |
| to memory | to memory | to memory | | to memory |
| address | address | address | | address |
| where | where | where | | where |
| packet | packet | packet | | packet |
| resides | resides | resides | | resides |
| write_time | write_time | write_time | . . . | write_time |

The hash key (KEY) is included in the failed packet array and is identical to that in the transmit array except that it can take on an EMPTY value. The hash_index is identical to that in the transmit array. The write_time is set to the sender's system clock at the time a packet's state information is moved from the transmit array to the failed packet array.

If the hash key is found in the failed packet array (Step 1108), then the state information for the failed packet with the lowest sequence number (and TTL>0, i.e., TTL not exceeded) is copied into the entry of the transmit array specified by the transmit descriptor (Step 1110). In one embodiment, the state information for the packet with the lowest sequence number is removed from the failed packet array and copied into the transmit array. Thus, packet itself is not copied to the transmit array, but the state information necessary to pull the packet from memory is copied into the transmit array.

If the hash key is not found in the failed packet array (Step 1108) or once all entries matching the hash key have been removed from the failed packet array, then the linked list of array memory (LLOAM) (one embodiment of memory 610) is traversed for new packets to transmit. Thus, in one embodiment, the cache table is searched for the hash key that is specified by the transmit descriptor (Step 1112). As with the storing of arriving packets, the cache/hash table combination shown in FIG. 9 is used to speed up the process of locating the hash key in the LLOAM.

If the hash key is found in the cache table 902 (Step 1114), then the hash index (hash_index) is obtained as pointer to the hash table 904 (Step 1116). Using the hash index as a pointer to the hash table 904, the state information for the new packet with the lowest available sequence number contained in the hash table 904 at this index is copied into the entry of the transmit array specified by the transmit descriptor (Step 1118). Thus, the transmit array is filled with state information for yet-to-be transmitted packets.

If the hash key is not found in the cache table 902 (Step 1114), then the hash table 904 is directly searched for the hash key (Step 1120). If the hash key is found in the hash table (Step 1122), then the state information for the new packet with the lowest available sequence number contained in the hash table 904 is copied into the entry of the transmit array specified by the transmit descriptor (Step 1118). If the hash key is not found in the hash table 904 (Step 1122), the entry in the transmit array is ignored and the packet transmitter goes to the next transmit array entry specified by the transmit descriptor (Step 1124).

This process continues at Step 1104 for a particular flow until the quantity of packets indicated by the transmit descriptor have been placed into the transmit array. The process is then repeated for each flow indicated by the transmit descriptor. When these processes are complete, the transmit array is formed. In some embodiments, the order of the transmit array is important as this is the order packets will be transmitted on the forward channel.

Referring next to FIG. 12, a flowchart is shown illustrating the steps performed, for example, by the acknowledgement processing mechanism of FIG. 4 or FIG. 6, when receiving acknowledgements from the receiver according to one embodiment of the invention. The acknowledgement processing mechanism receives a reply packet from the receiver over the feedback channel (Step 1202). The reply packet is a packet transmitted by the receiver to the sender via the feedback channel that indicates the result of a previous transmission of a packet on the forward channel. It is noted that the packet that was previously transmitted is currently within a given transmit array at the sender. A transmit array is an array of memory at the sender where packets that are sent on the channel are stored until an acknowledgement (either positive or negative) is received.

The contents of the reply packet are examined to determine whether or not a particular packet was received at the receiver error-free, i.e., the reply packet contains an ACK or a NACK for each transmitted packet. The reply packet or ARQ response can be received without error (i.e., passes CRC check), received with error(s) present (i.e., failed CRC check), or not be received at all (i.e., the channel “dropped” the ARQ response). An ARQ bit map is a mapping of whether or not the transmitted packets were positively (ACK) or negatively (NACK) acknowledged at the receiver. The ARQ bit map, used to move packet state information from the transmit array to the failed packet array, is generated from the ARQ response depending upon which of these three conditions occurred: (1) if the ARQ Response Packet passes CRC check, the ARQ bit map is the payload (arqbit_map) of the ARQ response packet; (2) if the ARQ Response Packet fails CRC check, the ARQ bit map consists entirely of FAIL; and (3) if the ARQ Response Packet is not received, the ARQ bit map consists entirely of FAIL.

If an ACK (positive acknowledgment) is received (Step 1204), the packet is discarded from the transmit array. If a NACK (negative acknowledgment) is received (Step 1204), then the packet is moved from the given transmit array to the failed packet array (Step 1208). The failed packet array is an array of memory at the sender, set aside on a per FID basis, used to store packets that have been transmitted and subsequently negatively acknowledged.

The following pseudo-code details several embodiments of the flow specific or flow independent selective-repeat ARQ techniques provided herein. According to one embodiment, these algorithms are actually embodied and implemented by the combination of the packet transmission mechanism 410, the acknowledgement processing mechanism 414, and the receiver 406. This pseudo-code could easily be implemented in a variety of forms. The terminology of Table 1 is used in the following pseudo-code.

This following pseudo-code illustrates several functions of one embodiment of the packet transmission mechanism 410 at the sender 402.

RESULT = CONTINUE
while (TRANSMIT_INSTANT == VALID && RESULT ==
CONTINUE)
{

if (exist FAILED_PACKET)
{

choose FAILED_PACKET within FAILED_PACKET_{—}

ARRAY with lowest SEQ_NO

if (FAILED_PACKET.TTL == 0)

discard FAILED_PACKET, RESULT = CONTINUE

else

send a copy of FAILED_PACKET on forward channel
FAILED_PACKET.TTL = FAILED_PACKET.TTL −1
place FAILED_PACKET in TRANSMIT_ARRAY
RESULT = STOP

}
else if (exist NEW_PACKET)
{

choose NEW_PACKET within NEW_PACKET_ARRAY with

lowest SEQ_NO

if (NEW_PACKET.TTL == 0)

discard NEW_PACKET, RESULT = CONTINUE

else

send a copy of NEW_PACKET on forward channel
NEW_PACKET.TTL = NEW_PACKET.TTL −1
place NEW_PACKET in TRANSMIT_ARRAY
RESULT = STOP

}
else
{

RESULT = STOP

}

}

The following pseudo-code describes the functions of one embodiment of the receiver in order to comply with the flow specific modified selective-repeat ARQ.

when PACKET received do:

if (PACKET.CRC == FAIL)
{

fid = PACKET.FID
seqno = PACKET.SEQ_NO
result = NACK

}
else
{

fid = PACKET.FID
seqno = PACKET.SEQ_NO
result = ACK

}
REPLY_PACKET = <result, fid, seqno>
send REPLY_PACKET to sender via feedback channel
place PACKET in RECEIVED_PACKET_ARRAY in order of

SEQ_NO
end

The following pseudo-code describes the functions of one embodiment of the acknowledgement processing mechanism 414 at the sender 402.

when REPLY_PACKET received do:

if (REPLY_PACKET.result == ACK)
{

discard packet in TRANSMIT_ARRAY with:

FID == REPLY_PACKET.fid && SEQ_NO ==

REPLY_PACKET.seqno

}
else
{

move from TRANSMIT_ARRAY to FAILED_PACKET_{—}

ARRAY the packet with:

FID == REPLY_PACKET.fid && SEQ_NO ==

REPLY_PACKET.seqno

}

end

The following pseudo-code describes the process for moving a packet's state information from the transmit array to the failed packet array by the acknowledgement processing mechanism 414 according to one embodiment of the invention.

pt_index = 1

| | |
|---|---|
| for i = 1 to size_of(transmit_array), i increments by one | { |

| pkt_state = transmit_array[i] | |
|---|---|
| pkt = packet in LLOAM pointed to by pkt_state.ptr | |
| pkt.TTL = pkt.TTL - 1 | |
| if(arq_bit_map[i] == FAIL && pkt.TTL > 0) | { |

while(failed_packet_array[pt_index].KEY != EMPTY &&

(system_clock -

failed_packet_array[pt_index].write_time) <= MAX_PT_TIME)
{

pt_index = pt_index +1

}
failed_packet_array[pt_index].KEY = pkt_state.KEY
failed_packet_array[pt_index].hash_index = pkt_state.hash_index
failed_packet_array[pt_index].ptr = pkt_state.ptr
failed_packet_array[pt_index].write_time = system_clock

}
else

do nothing

}
clear transmit_array

It is noted that special care must be taken on the selection of the MAX_PT_TIME in this pseudo-code and the size of the failed packet array to insure that the “while” loop does not become infinite. This algorithm transfers the state information of all packets in the transmit array that fail ARQ. When this state information is transferred, the element in the failed packet array to which it is moved is either empty or is expired. From the pseudo-code it is clear that the expiration time is MAX_PT_TIME.

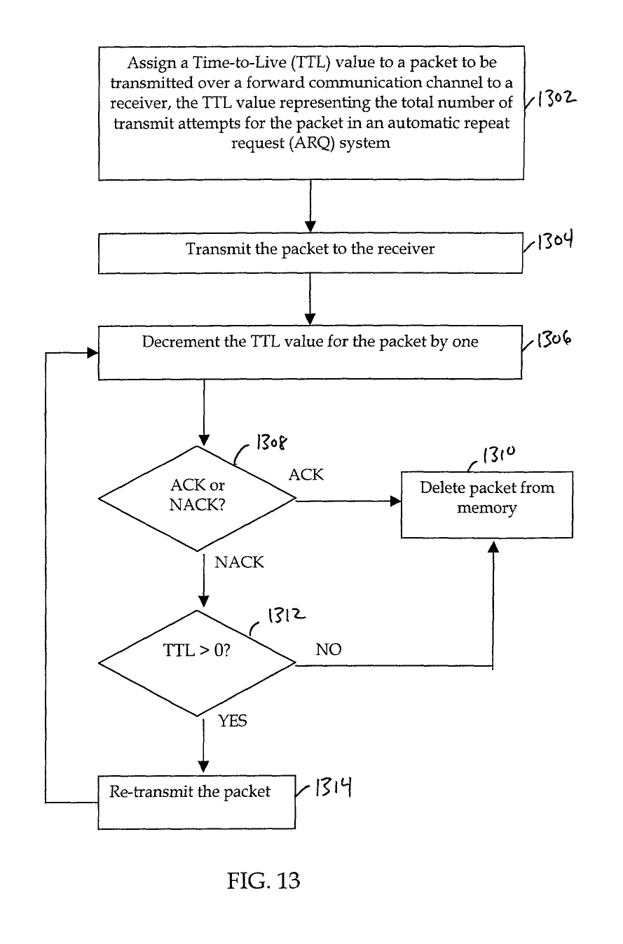

Referring next to FIG. 13, a flowchart is shown illustrating the steps performed in assigning a time-to-live value to a given packet as a function of the type of service according to one embodiment of the invention. In some embodiments, a time-to-live (TTL) value is assigned to each packet corresponding to the type of service (TOS) when using the flow specific or flow independent ARQ techniques described herein. However, in some embodiments, the assignment of a TTL is employed in a regular ARQ system that is not flow specific or flow independent as described above. Thus, the assignment of a TTL value for packets may be used with any type of ARQ, e.g., stop-and-wait ARQ, go-back-N ARQ and selective-repeat ARQ, with or without multiple flows of packets.

Initially, a time-to-live (TTL) value is assigned to each packet that is to be transmitted over a forward channel to a receiver (Step 1302). In some embodiments, the assigning step includes saving the TTL in memory, either with the packet or in a separate location of memory but corresponding to the packet. The TTL value represents the total number of transmission attempts that will be allowed for the given packet, including the initial transmission attempt and any re-transmission attempts using an ARQ mechanism. For example, if a given packet has a TTL value of 3, then it may be transmitted a total of three times, i.e., the initial transmission attempt plus 2 re-transmission attempts. The TTL value is a function of the type of service of the packet. For example, a video packet, and audio packet and a data packet all have different types of service associated therewith. A simple lookup table matching given types of service (TOS) with TTL values may be stored in memory at the sender.

Next, the packet is transmitted to the receiver over the forward channel (Step 1304). Then, the TTL assigned to the packet is decremented by one (Step 1306), since one transmission attempt is made.

If an ACK of the packet is received from the reverse channel (Step 1308), the packet is deleted from memory at the sender (Step 1310). Thus, the packet is no longer needed at the sender since the packet was successfully received at the receiver.

If a NACK is received from the reverse channel (Step 1308), the TTL of the packet is checked to see if the TTL is greater than zero. If the TTL is greater than zero (Step 1312), the packet is re-transmitted according to the ARQ technique (Step 1314).

If the TTL is not greater than zero (Step 1314), the packet is deleted from memory (Step 1310). The packet is deleted since the packet has exceeded the assigned TTL value. In other words, the packet is no longer useful to the receiver; thus, to re-transmit a useless packet is a waste system resources.

This is in contrast to known systems that discard a packet after a determination that the channel conditions are not good and not amount of re-transmitting will result in a positive acknowledgement. The time-to-live automatically sets a limit on the total number of transmission attempts based on the type of service (TOS), not the conditions of the channel.

It is also noted that the determination that the assigned TTL has been exceeded may be made in many ways. For example, a separate transmission counter may be maintained for each packet and incremented at each transmission attempt and when the counter equals the TTL value, the packet will be discarded and no longer transmitted. Thus, the TTL assigned to packet is exceeded when the number of transmit attempts will exceed the TTL value.

It is also noted that the steps of FIGS. 7-8 and 10-13 may be performed by the functional components of the packet transmission mechanism 410 and the acknowledgement processing mechanism 414 of FIGS. 4 and 6. These steps may be performed as a set of instructions that are performed in dedicated hardware or in software using a processor or other machine to execute the instructions to accomplish the given steps.

While the invention herein disclosed has been described by means of specific embodiments and applications thereof, numerous modifications and variations could be made thereto by those skilled in the art without departing from the scope of the invention set forth in the claims.

What is claimed is:

1. A method of automatic repeat request (ARQ) for a plurality of packets to be transmitted to a receiver comprising:
performing automatic repeat request for packets belonging to respective ones of a plurality of packet flows independent from and without affecting the transmission of packets of others of the plurality of packet flows, wherein each of the plurality of packet flows corresponds to a specified type of service.

2. The method of claim 1 further comprising parsing each of the plurality of packets to be transmitted to the receiver into a respective one of the plurality of packet flows.

3. The method of claim 2 further comprising storing each of the plurality of packets into a location in memory based upon packet flow.

4. The method of claim 1 wherein the performing step comprises transmitting the plurality of packets to the receiver by packet flow according to a transmit descriptor, the transmit descriptor specifying at least how many packets of which of the plurality of packet flows to transmit to the receiver.

5. The method of claim 1 wherein the performing step comprises assigning a time-to-live value to each packet to be transmitted to the receiver, the time-to-live value representing the maximum number of transmit attempts of the packet to the receiver including re-transmit attempts in performing the automatic repeat request.

6. The method of claim 5 wherein the time-to-live value is assigned based upon the type of service of the packet.

7. The method of claim 5 further comprising decrementing the time-to-live value after each transmit attempt.

8. The method of claim 1 wherein the performing step comprises:
transmitting packets from two or more of the plurality of packet flows to the receiver;
receiving an acknowledgement from the receiver, the acknowledgement indicating whether or not each of the packets were received in error; and
re-transmitting a respective packet of a respective one of the plurality of packet flows, in the event the acknowledgement indicates that the respective packet was received in error, without affecting the subsequent transmission of packets of others of the plurality of packet flows.

9. The method of claim 8 wherein the transmitting step comprises transmitting the packets within a single transmit frame and wherein the re-transmitting step comprises re-transmitting the respective packet within a subsequent single transmit frame without affecting the subsequent transmission of the packets of the others of the plurality of packet flows within the subsequent single transmit frame.

10. The method of claim 1 wherein the performing step comprises performing the automatic repeat request for the packets belonging to the respective ones of the plurality of packet flows and transmitted within a single transmit frame independent from and without affecting the transmission of the packets of the others of the plurality of packet flows transmitted within the single transmit frame.

11. The method of claim 1 wherein the performing step comprises performing selective-repeat automatic repeat request for the packets belonging to the respective ones of the plurality of packet flows independent from and without affecting the transmission of the packets of the others of the plurality of packet flows.

12. A method of automatic repeat request (ARQ) for a plurality of packets to be transmitted to a receiver comprising:
performing automatic repeat request on a first set of one or more packets transmitted in a first portion of a transmit frame, wherein the first set of one or more packets belong to a respective one of a plurality of packet flows; and
performing automatic repeat request on a second set of one or more packets transmitted in a second portion of the transmit frame, wherein the second set of one or more packets belong to another respective one of the plurality of packet flows,
wherein the automatic repeat request performed on the first set of one or more packets is independent from and does not affect the transmission of packets in the second portion of the transmit frame.

13. The method of claim 12 wherein the automatic repeat request performed on the second set of one or more packets is independent from and does not affect the transmission of packets in the first portion of the transmit frame.

14. The method of claim 12 wherein each of the plurality of packet flows contains packets having one of a plurality of types of service.

15. The method of claim 12 wherein the performing steps comprise performing selective-repeat automatic repeat request.

16. An automatic repeat request system comprising:
means for performing automatic repeat request for packets belonging to respective ones of a plurality of packet flows independent from and without affecting the transmission of packets of others of the plurality of packet flows, wherein each of the plurality of packet flows corresponds to a specified type of service.

17. The system of claim 16 wherein the means for performing comprises means for assigning a time-to-live value to each packet to be transmitted to the receiver, the time-to-live value representing the maximum number of transmit attempts of the packet to the receiver including re-transmit attempts in performing the automatic repeat request.

18. The system of claim 16 wherein the means for performing comprise means for performing the automatic repeat request for the packets belonging to the respective ones of the plurality of packet flows and transmitted within a single transmit frame independent from and without affecting the transmission of the packets of the others of the plurality of packet flows transmitted within the single transmit frame.

19. The system of claim 16 wherein the means for performing comprises:
a packet transmission mechanism for transmitting packets from two or more of the plurality of packet flows to the receiver;
an acknowledgement processing mechanism for receiving an acknowledgement from the receiver, the acknowledgement indicating whether or not each of the packets were received in error; and
the packet transmission mechanism for re-transmitting a respective packet of a respective one of the plurality of packet flows, in the event the acknowledgement indicates that the respective packet was received in error, without affecting the subsequent transmission of packets of others of the plurality of packet flows.

20. A method of automatic repeat request (ARQ) comprising:
assigning a time-to-live value to a packet to be transmitted over a forward communication channel to a receiver, the time-to-live value representing a maximum number of transmit attempts of the packet over the forward communication channel including re-transmit attempts using the automatic repeat request, the time-to-live value corresponding to a type of service corresponding to the packet.

21. The method of claim 20 further comprising transmitting the packet over the forward communication channel to the receiver.

22. The method of claim 20 further comprising:
receiving a negative acknowledgement from the receiver via a reverse communication channel, the negative acknowledgement indicating that the packet was received in error;
re-transmitting the packet to the receiver, in the event a number of transmit attempts of the packet including re-transmit attempts using the automatic repeat request does not exceed the time-to-live value.

23. The method of claim 22 further comprising:
decrementing the time-to-live value by one; and
wherein the re-transmitting step comprises re-transmitting the packet to the receiver, in the event the time-to-live value is greater than zero.

24. The method of claim 22 further comprising deleting the packet from memory, in the event the total number of transmit attempts of the packet exceeds the time-to-live value.

25. The method of claim 20 wherein the time-to-live value represents n transmit attempts available for the packet and further comprising deleting the packet from memory after n transmit attempts including re-transmit attempts using the automatic repeat request.
